(19) United States
(12) Patent Application Publication
(10) Pub. No.: US 2026/0096388 A1
(43) Pub. Date: Apr. 2, 2026

(54) COVER OPTIMIZATION FOR SUBSTRATE-BASED PROCESS CONDITION MEASUREMENT DEVICE

(71) Applicant: KLA Corporation, Milpitas, CA (US)

(72) Inventors: Farhat A. Quli, Castro Valley, CA (US); Jing Zhou, Castro Valley, CA (US); Razieh Mahzoon, Hayward, CA (US)

(21) Appl. No.: 19/311,525

(22) Filed: Aug. 27, 2025

Related U.S. Application Data
(60) Provisional application No. 63/699,855, filed on Sep. 27, 2024.

(51) Int. Cl. H01L 21/67; H01J 37/32

(52) U.S. Cl. CPC H10P 72/0604; H01J 37/32935

(57) ABSTRACT

A process condition measurement device may include a substrate and a cover. The cover may cover the substrate to protect sensors and interconnects from a process environment, such as from corrosive gases, plasma, and radio frequency signals. The cover may uncover portions of the substrate to improve the thermo-mechanical behavior of the substrate. The cover may uncover portions of the substrate by blank-through holes which are offset from the sensors and interconnects. The cover may also uncover portions of the substrate by grooves formed through the cover. The process condition measurement device may also include a thin-film which is formed over the interconnects. The thin-film may protect interconnects from the process environment. The blank-through holes, the grooves, and the thin-films may be used separately or in combination.

### CROSS-REFERENCE

The present application claims the benefit under 35 U.S.C. § 119 of U.S. Provisional application 63/699,855, filed on Sep. 27, 2024, titled “Cover Optimization for Substrate-Based Process Condition Measurement Device”, which is incorporated herein by reference in the entirety.

### TECHNICAL FIELD

The present disclosure generally relates to monitoring of wafers along a semiconductor process line, and more particularly to process condition monitoring wafers.

### BACKGROUND

As tolerances on process conditions in semiconductor device processing environments continue to narrow, the demand for improved process monitoring systems continues to increase. Current devices which measure the process conditions may exhibit thermo-mechanical behaviors due to stress imparted by a cover wafer. Therefore, it would be desirable to provide a device and system to allow for high temperature measurement using an instrumented wafer to monitor the conditions of a semiconductor device processing line.

### SUMMARY

A process condition measurement device is described, in accordance with one or more embodiments of the present disclosure. The process condition measurement device may include: a substrate; a cover disposed above and covering the substrate, wherein the cover extends across the substrate, wherein the cover defines a plurality of blank-through holes, wherein the plurality of blank-through holes is defined axially through the cover; a plurality of sensors configured to measure processing conditions across the substrate; and a plurality of interconnects electrically connecting the plurality of sensors, wherein the plurality of sensors and the plurality of interconnects are disposed on or embedded within the substrate, wherein the plurality of blank-through holes is offset from the plurality of sensors and the plurality of interconnects.

A system is described, in accordance with one or more embodiments of the present disclosure. The system may include: a process condition measurement device including: a substrate; a cover disposed above and covering the substrate, wherein the cover extends across the substrate, wherein the cover defines a plurality of blank-through holes, wherein the plurality of blank-through holes is defined axially through the cover; a plurality of sensors configured to measure processing conditions across the substrate; and a plurality of interconnects electrically connecting the plurality of sensors, wherein the plurality of sensors and the plurality of interconnects are disposed on or embedded within the substrate, wherein the plurality of blank-through holes is offset from the plurality of sensors and the plurality of interconnects; and a front opening unified pod configured to receive the process condition measurement device.

A process condition measurement device is described, in accordance with one or more embodiments of the present disclosure. The process condition measurement device may include: a substrate; a cover disposed above and covering the substrate, wherein the cover extends across the substrate, wherein the cover includes a plurality of cover sections, wherein the plurality of cover sections define a plurality of grooves, wherein the plurality of grooves is defined axially through at least a partial thickness of the cover; a plurality of sensors configured to measure processing conditions across the substrate; and a plurality of interconnects electrically connecting the plurality of sensors, wherein the plurality of sensors and the plurality of interconnects are disposed on or embedded within the substrate.

A process condition measurement device is described, in accordance with one or more embodiments of the present disclosure. The process condition measurement device may include: a substrate; a plurality of sensors configured to measure processing conditions across the substrate; a plurality of interconnects electrically connecting the plurality of sensors, wherein the plurality of sensors and the plurality of interconnects are disposed on or embedded within the substrate, wherein the plurality of interconnects include: a cap layer disposed on the substrate; an interconnect layer disposed on the cap layer, wherein a width of the cap layer extends beyond a width of the interconnect layer; and an interconnect-passivation layer formed over the cap layer and the interconnect layer, wherein the interconnect-passivation layer is disposed on the substrate; and a thin-film formed over the plurality of interconnects, wherein the thin-film includes: a conductive shield formed over the interconnect-passivation layer and disposed on the substrate; and a thin-film-passivation layer formed over the conductive shield and disposed on the substrate.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the description and drawings serve to explain the principles of the disclosure.

### BRIEF DESCRIPTION OF THE DRAWINGS

The numerous advantages of the disclosure may be better understood by those skilled in the art by reference to the accompanying figures in which:

FIG. 1A illustrates a top view of a process condition measurement device with a cover including package-through holes and blank-through holes, in accordance with one or more embodiments of the present disclosure.

FIG. 1B illustrates a top view of the process condition measurement device with the cover and the adhesive layer hidden to illustrate an exemplary configuration of sensors and interconnects disposed on or embedded within a substrate, in accordance with one or more embodiments of the present disclosure.

FIG. 1C illustrates a top view of the process condition measurement device with the cover and the adhesive layer hidden and the package-through holes and blank-through holes illustrated on the substrate as dashed lines to illustrate the blank-through holes being offset from the sensors and the interconnects, in accordance with one or more embodiments of the present disclosure.

FIG. 1D illustrates an exploded view of the process condition measurement device, in accordance with one or more embodiments of the present disclosure.

FIG. 1E illustrates a partial cross-section of the process condition measurement device illustrating one of the blank-through holes which is offset from the sensor, a length of the interconnect, and an electrical contact, in accordance with one or more embodiments of the present disclosure.

FIG. 2A illustrates a partial cross-section of the process condition measurement device illustrating one of the blank-through holes which is offset from the sensor and the length of the interconnect and with a groove being disposed over the interconnect, in accordance with one or more embodiments of the present disclosure.

FIG. 2B illustrates a top view of the process condition measurement device with the cover including grooves and the blank-through holes, where the grooves are gridded grooves, in accordance with one or more embodiments of the present disclosure.

FIG. 2C illustrates a top view of the process condition measurement device with the cover including the grooves but not the blank-through holes, where the grooves are the gridded grooves, in accordance with one or more embodiments of the present disclosure.

FIG. 2D illustrates a top view of the process condition measurement device with the cover including the grooves and the blank-through holes, where the grooves are concentric grooves, in accordance with one or more embodiments of the present disclosure.

FIG. 2E illustrates a top view of the process condition measurement device with the cover including the grooves but not the blank-through holes, where the grooves are the concentric grooves, in accordance with one or more embodiments of the present disclosure.

FIG. 2F illustrates a top view of the process condition measurement device with the cover including the grooves and the blank-through holes, where the grooves are sectored grooves, in accordance with one or more embodiments of the present disclosure.

FIG. 2G illustrates a top view of the process condition measurement device with the cover the grooves but not the blank-through holes, where the grooves are the sectored grooves, in accordance with one or more embodiments of the present disclosure.

FIG. 3A illustrates a partial cross-section of the process condition measurement device illustrating a width of the interconnect and a thin-film covering the interconnect and with the process condition measurement device not including the adhesive layer and the cover, in accordance with one or more embodiments of the present disclosure.

FIG. 3B illustrates a partial cross-section of the process condition measurement device illustrating the width of the interconnect and the thin-film covering the interconnect and with the process condition measurement device including the adhesive layer and the cover, in accordance with one or more embodiments of the present disclosure.

FIG. 3C illustrates a partial cross-section of the process condition measurement device illustrating the thin-film in the process of covering the interconnect, in accordance with one or more embodiments of the present disclosure.

FIG. 4 depicts a simplified block diagram of a system with the process condition measurement device, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to a cover optimization for a substrate-based process condition measurement device. A process condition measurement device may include a substrate and a cover. The cover may cover the substrate to protect sensors and interconnects from a process environment, such as from corrosive gases, plasma, and radio frequency signals. The cover may uncover portions of the substrate to improve the thermo-mechanical behavior of the substrate. The cover may uncover portions of the substrate by blank-through holes which are offset from the sensors and interconnects. The cover may also uncover portions of the substrate by grooves formed through the cover. The process condition measurement device may also include a thin-film which is formed over the interconnects. The thin-film may protect interconnects from the process environment. The blank-through holes, the grooves, and the thin-films may be used separately or in combination.

U.S. Patent Publication Number US20050284570A1, titled “Diagnostic plasma measurement device having patterned sensors and features”; U.S. Patent Publication Number US20060171848A1, titled “Diagnostic plasma sensors for endpoint and end-of-life detection”; U.S. Patent Publication Number US20110074341A1, titled “Non-contact interface system”; U.S. Patent Publication Number US20220189803A1, titled “Sensor configuration for process condition measuring devices”; U.S. Patent Publication Number US20250054789A1, titled “Method of fabrication and implementation of process condition measurement device”; U.S. Patent Publication Number US20250137844A1, titled “Metrology method of calibrating and monitoring radiation in euv lithographic systems”; U.S. Pat. No. 6,616,332B1, titled “Optical techniques for measuring parameters such as temperature across a surface”; U.S. Pat. No. 7,127,362B2, titled “Process tolerant methods and apparatus for obtaining data”; U.S. Pat. No. 7,497,134B2, titled “Process condition measuring device and method for measuring shear force on a surface of a substrate that undergoes a polishing or planarization process”; U.S. Pat. No. 7,531,984B2, titled “Sensor apparatus power transfer, communication and maintenance methods and apparatus”; U.S. Pat. No. 7,555,948B2, titled “Process condition measuring device with shielding”; U.S. Pat. No. 7,698,952B2, titled “Pressure sensing device”; U.S. Pat. No. 7,855,549B2, titled “Integrated process condition sensing wafer and data analysis system”; U.S. Pat. No. 8,033,190B2, titled “Process condition sensing wafer and data analysis system”; U.S. Pat. No. 8,104,342B2, titled “Process condition measuring device”; U.S. Pat. No. 9,1341,86B2, titled “Process condition measuring device (PCMD) and method for measuring process conditions in a workpiece processing tool configured to process production workpieces”; U.S. Pat. No. 9,222,842B2, titled “High temperature sensor wafer for in-situ measurements in active plasma”; U.S. Pat. No. 9,356,822B2, titled “Automated interface apparatus and method for use in semiconductor wafer handling systems”; U.S. 9,719,867B2, titled “Method And System For Measuring Heat Flux”; U.S. Pat. No. 10,215,626B2, titled “Method and system for measuring radiation and temperature exposure of wafers along a fabrication process line”; U.S. Pat. No. 10,460,966B2, titled “Encapsulated instrumented substrate apparatus for acquiring measurement parameters in high temperature process applications”; U.S. Pat. No. 10,7203,50B2, titled “Etch-resistant coating on sensor wafers for in-situ measurement”; U.S. Pat. No. 10,777,393B2, titled “Process condition sensing device and method for plasma chamber”; U.S. Pat. No. 11,150,140B2, titled “Instrumented substrate apparatus for acquiring measurement parameters in high temperature process applications”; U.S. Pat. No. 11,569,138B2, titled “System and method for monitoring parameters of a semiconductor factory automation system”; U.S. Pat. No. 11,688,614B2, titled “Mitigating thermal expansion mismatch in temperature probe construction apparatus and method”; U.S. Pat. No. 11,784,071B2, titled “Process temperature measurement device fabrication techniques and methods of calibration and data interpolation of the same”; are each incorporated herein by reference in the entirety.

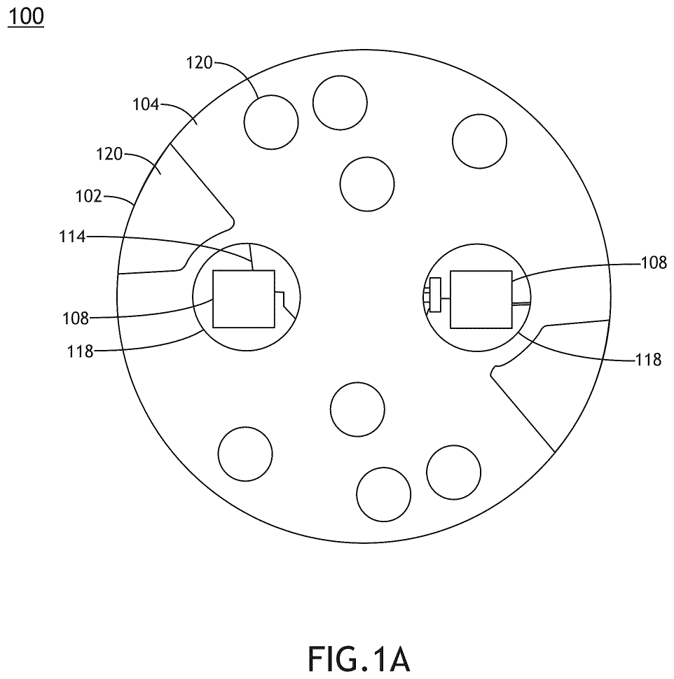

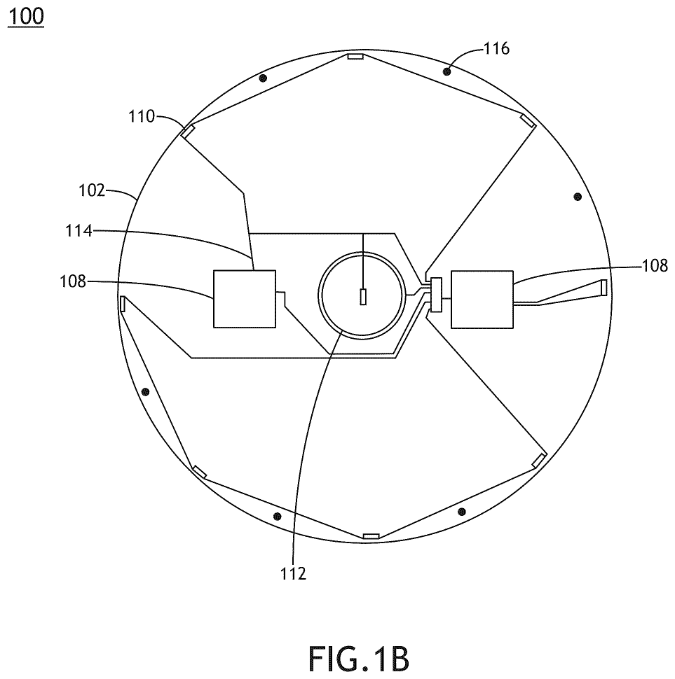

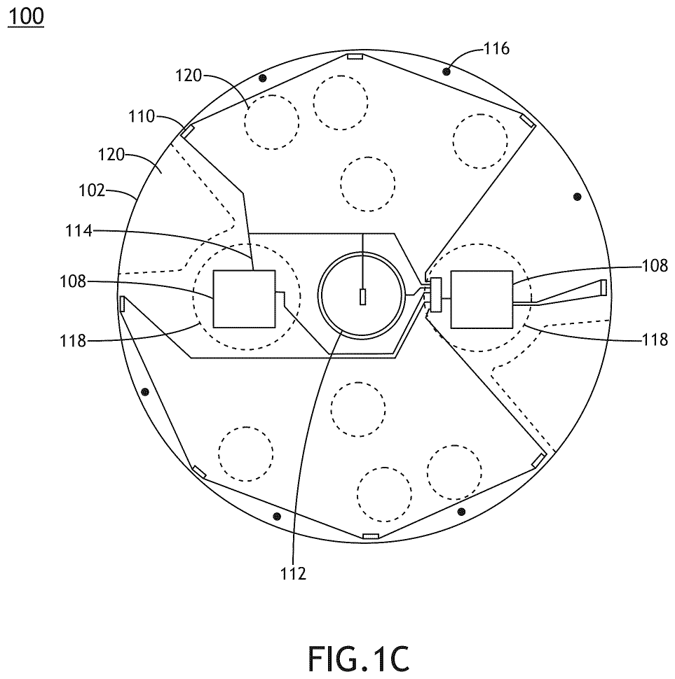

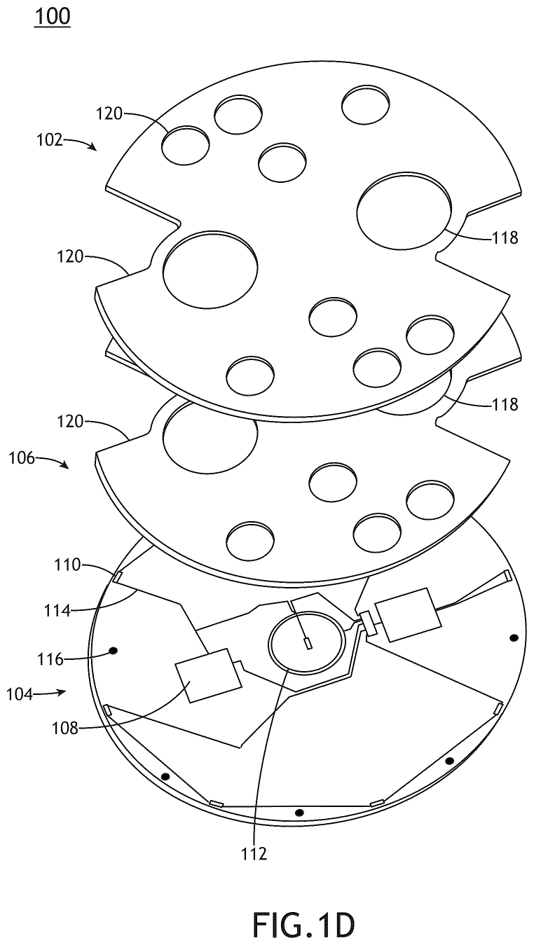

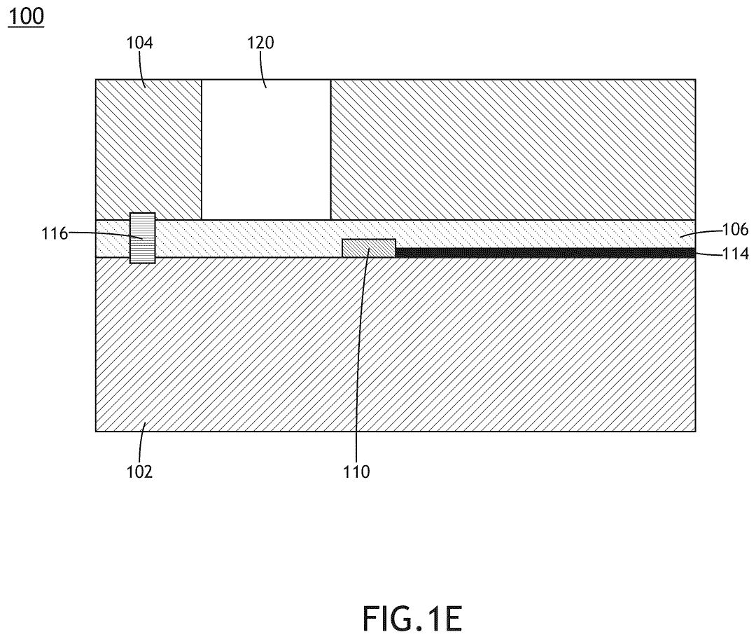

FIGS. 1A-1E illustrate a process condition measurement device 100 (PCMD), in accordance with one or more embodiments of the present disclosure. The process condition measurement device 100 may be an instrumented substrate assembly, substrate device, instrumented wafer, instrumented wafer substrate, sensor wafer, substrate monitoring device, instrumented substrate device, inspection substrate, inspection wafer, measurement wafer, registration measuring substrate, registration wafer, and the like.

The process condition measurement device 100 may include one or more components, such as, but not limited to, a substrate 102, a cover 104, an adhesive layer 106, component packages 108, sensors 110, a communication interface 112, interconnects 114, electrical contacts 116, package-through holes 118, blank-through holes 120, and the like.

The substrate 102 may include a top surface and/or a bottom surface. The top surface and/or the bottom surface of the substrate 102 may be planar. It is further contemplated that the top surface may be non-planar while the bottom surface may be planar. For example, the substrate 102 may define cavities (not depicted). The cavities may be defined by etching, precision grinding, or the like. Any of the various components of the process condition measurement device 100 may be embedded in the cavities, and thereby be embedded within the substrate 102.

The process condition measurement device 100 may include the cover 104. The cover 104 may be disposed above the substrate 102. The cover 104 may extend across the substrate 102. For example, the cover 104 extend across the substrate 102 to match the diameter of the substrate 102. The substrate 102 and the cover 104 may include a same shape. The cover 104 may only be over selected areas of the substrate 102, such as over the traces and the interconnects 114.

The substrate 102 and the cover 104 may be referred to as respective of a substrate wafer and a cover wafer. The substrate 102 and/or the cover 104 may take on the same, or similar, size and shape as a standard substrate processed by a semiconductor device processing system. The substrate 102 and/or the cover 104 may have physical parameters that approximate the physical parameters of a production substrate used in the manufacture of integrated circuits or other electronics. The substrate 102 and/or the cover 104 may have dimensions conforming to that of a Semiconductor Equipment and Materials International (SEMI®) wafer. The substrate 102 and/or the cover 104 may include a round substrate (e.g., a round wafer) having a selected diameter. For example, the substrate 102 may have a diameter between 25 and 450 mm, such as, but not limited to, 25 mm, 50 mm, 75 mm, 100 mm, 125 mm, 150 mm, 200 mm, 300 mm, or 450 mm. For instance, the substrate 102 and/or the cover 104 may include a diameter between 100 and 300 mm. Additionally, the substrate 102 may have a thickness between 0.275 and 2 mm (e.g., 1.4 mm). The thickness may be based on the diameter. The substrate 102 may also have a thickness that approximates the corresponding thickness of the production substrate, although the thickness may be slightly larger than the production substrate to accommodate additional electronics and/or other components of the process condition measurement device 100. The thickness of the cover 104 may be thinner than the substrate 102.

The substrate 102 and/or the cover 104 may include any suitable material. For example, the substrate 102 and/or the cover 104 may include a wafer. For example, the substrate 102 and/or the cover 104 may include a wafer structure formed from silicon (e.g., single crystal silicon), silicon carbide, silicon nitride, silicon dioxide (e.g., quartz), doped (e.g., n-type or p-type) silicon, glass (e.g., fused silica glass wafer, borosilicate glass wafer, and the like), carbon fiber stabilized epoxy matrices, one or more ceramic materials, glass carbon fibers, one or more composite materials, or a combination thereof. For example, the substrate 102 and/or the cover 104 may be formed from a composite material including two or more layers of material that may be bonded together or two or more materials that may be intermixed in a single layer or multiple layers. The substrate 102 and/or the cover 104 may also be a composite material such as graphite/epoxy or a laminate formed from silicon, graphite/epoxy, silicon. The substrate 102 and/or the cover 104 may be made of the same or similar materials to a production substrate. The substrate 102 and the cover 104 may or may not be made of the same material. For example, each of the substrate 102 and the cover 104 may be made of silicon. By way of another example, the substrate 102 may be made of silicon and the cover 104 be made of a glass (e.g., an etch-resistant glass). The glass cover may resist etching. For example, the cover 104 may be formed from fused-silica. The material properties of the substrate 102 and the cover 104 may be selected to accommodate thermal expansion without cracking and/or warpage. For example, the substrate 102 and the cover 104 may include a matching thermal expansion coefficient.

The cover 104 may be mechanically coupled to the substrate 102. For example, the cover 104 may be mechanically coupled to the substrate 102 by the adhesive layer 106, or the like. The adhesive layer 106 may be disposed between and adhere together the substrate 102 and the cover 104. The adhesive layer 106 may include kind of substrate adhesive, such as, but not limited to, silicone adhesive, epoxy adhesive, or the like. The adhesive layer 106 may be selected based on a thermal expansion of the adhesive layer 106 to not impart stress to the substrate 102, and/or to not damage the substrate 102 during curing. The adhesive layer 106 may include a thickness on the order of tens of micrometers. The adhesive layer 106 may laminate the cover 104 to the substrate 102.

The cover 104 may be disposed over and cover one or more components of the process condition measurement device 100. For example, the cover 104 may be disposed over and cover the sensors 110, the communication interface 112, the interconnects 114, and/or the electrical contacts 116. For instance, the sensors 110, the communication interface 112, the interconnects 114, and/or the electrical contacts 116 may be sandwiched between the substrate 102 and the cover 104. The cover 104 may cover the sensors 110, the communication interface 112, the interconnects 114, and/or the electrical contacts 116 for physical and electrical shielding purposes. The cover 104 may cover the components to prevent the components from being exposed to aggressive process conditions, protecting the components from the chemical environment of the process (such as corrosive gasses or plasma), providing electronic shielding to the components, preventing the components from being bombarded by plasma or subject to radio frequency and other radiation, protecting the process environment from contamination by the components on the substrate 102, and the like. For example, the cover 104 may prevent etching the various components when subject to process conditions by covering said components. For example, the cover 104 may shield the various components from EUV radiation or the like. The cover 104 may or may not cover the component packages 108. In embodiments, the cover 104 does not cover the component packages 108.

The cover 104 may define package-through holes 118 and/or blank-through holes 120. The package-through holes 118 and/or the blank-through holes 120 may be defined axially through the cover 104. The package-through holes 118 and/or the blank-through holes 120 may include any suitable shape. For example, the package-through holes 118 and/or the blank-through holes 120 may be a cylinder, a polygonal shape, or the like. The adhesive layer 106 may also define the package-through holes 118 and/or the blank-through holes 120 with the cover 104.

The component packages 108 may be aligned with and extend axially through the package-through holes 118. The component packages 108 may be uncovered by the cover 104 due to the component packages 108 extending axially through the package-through holes 118. Instead, the component packages 108 may be protected by one or more enclosures and/or heat-sinks of the component packages 108. Portions of the interconnects 114 which connect to the component packages 108 may be uncovered by the cover 104 due to the package-through holes 118. The portions of the interconnects 114 which are uncovered by the cover 104 may be shielded by one or more additional films (e.g., thin-film 312).

The blank-through holes 120 may be offset from the component packages 108, the sensors 110, the communication interface 112, the interconnects 114, the electrical contacts 116, and/or the package-through holes 118. For example, the blank-through holes 120 may be radially and/or circumferentially offset from the component packages 108, the sensors 110, the communication interface 112, the interconnects 114, and/or the electrical contacts 116. None of the components of the process condition measurement device 100 may be disposed in or aligned with the blank-through holes 120. In this regard, the cover 104 uncovers portions of the substrate 102 which do not include the component packages 108, the sensors 110, the communication interface 112, the interconnects 114, and/or the electrical contacts 116. The portions of the substrate 102 which are uncovered by the blank-through holes 120 may be unprotected from the processing conditions. The blank-through holes 120 may be disposed at one or more locations within the cover 104. The blank-through holes 120 may be defined in the cover 104 above locations on the substrate 102 which do not include the sensors 110, the communication interface 112, the interconnects 114, and/or the electrical contacts 116. It is noted that the arrangement and number of the blank-through holes 120 depicted are not limiting and are provided merely for illustrated purposes. The blank-through holes 120 may be configured in several patterns, shapes, and quantities. One consideration in the location of the blank-through holes 120 may be to ensure that the cover 104 is disposed over and covers the sensors 110, the communication interface 112, the interconnects 114, and/or the electrical contacts 116. The blank-through holes 120 may be considered blank by not uncovering any of the various components of the process condition measurement device 100.

The blank-through holes 120 may reduce the total area of the substrate 102 that is covered by the cover 104. Reducing the area in which the cover 104 covers the substrate 102 may be beneficial to reduce excess mass of the process condition measurement device 100 (e.g., to improve ease-of-handling), reducing thermal-mass (e.g., to more accurately represent the temperature of an actual substrate undergoing the process), or the like.

One or more components of the process condition measurement device 100 may be disposed on the top surface and/or embedded within the substrate 102. For example, the component packages 108, the sensors 110, the communication interface 112, the interconnects 114, and/or the electrical contacts 116 may be disposed on and/or embedded within the substrate 102. Any of the various components of the process condition measurement device 100 may be disposed at one or more locations on and/or embedded within the substrate 102. It is noted that the arrangement and number of the component packages 108, the sensors 110, the communication interface 112, the interconnects 114, and/or the electrical contacts 116 depicted are not limiting and are provided merely for illustrated purposes. The component packages 108, the sensors 110, the communication interface 112, the interconnects 114, and/or the electrical contacts 116 may be configured in several patterns, shapes, and quantities. One consideration in the location of the various components of the process condition measurement device 100 on and/or embedded within the substrate 102 may be to maintain a center of gravity of the process condition measurement device 100 at a center of the substrate 102. The communication interface 112 may also be concentric with a center of the substrate 102 to maintain communication regardless of the orientation of the process condition measurement device 100. Furthermore, the interconnects 114 may connect between the sensors 110 in any suitable network topology.

Any of the various components of the process condition measurement device 100 may be disposed on or embedded in the substrate 102 using any suitable technique. For example, the component packages 108, the sensors 110, the communication interface 112, the interconnects 114, and/or the electrical contacts 116 may be disposed on or embedded in the substrate 102 via microelectromechanical system (MEMS) fabrication or semiconductor device fabrication techniques, such as, but not limited to, wet etching, dry etching, or electrical discharge machining.

The process condition measurement device 100 may include the component packages 108. The component packages 108 may provide various functionality to the process condition measurement device 100. The component packages 108 may provide data collection and data storage functionality to the process condition measurement device 100. The component packages 108 may be configured to receive and/or store data including, but not limited to, data from the sensors 110 and/or the communication interface 112. For example, the component packages 108 may store sensor measurements of the process conditions from the sensors 110. The component packages 108 may also provide data processing functionality to the process condition measurement device 100. The component packages 108 may be configured to calculate one or more values based on the sensor measurements. For example, in the case of temperature, the sensors 110 may be configured to generate thermocouple voltages (measurement parameters) indicative of temperature, and the component packages 108 may be configured to calculate a temperature based on the thermocouple voltages. The component packages 108 may also control data flow to and/or from the process condition measurement device 100. For example, the component packages 108 may be configured to send the sensor measurements and/or the values calculated based on the sensor measurements from the process condition measurement device 100 through the communication interface 112. The component packages 108 may also provide a power supply functionality for the process condition measurement device 100. The component packages 108 may provide power to any of the various components of the process condition measurement device 100.

The component packages 108 may include any suitable components (not depicted) for providing the functionality, such as, but not limited to, a controller, a memory, processors, a power source, and the like. The power source may include one or more batteries (e.g., rechargeable batteries), a wired power source, or the like. The controller may include the memory and the processors. The memory may store the processing conditions and program instructions for the operation of the process condition measurement device 100. The processors may be configured to execute the program instructions maintained on the memory, the program instructions causing the component packages 108 to execute any of the various process steps described. The power source may optionally include one or more solar cells. The power source may provide power storage functionality to the process condition measurement device 100. The component packages 108 may also include an enclosure (not depicted) to insulate or shield any of the various components thermally and/or electrically.

The process condition measurement device 100 may include the sensors 110. The sensors 110 may be arranged in any suitable pattern. As depicted, the sensors 110 are arranged in a ring topology, although this is not intended to be limiting. The sensors 110 may be disposed on and/or embedded within the substrate 102.

The sensors 110 may generate sensor measurements. The sensor measurements may be generated by measuring one or more processing conditions. The sensors 110 may measure the processing conditions. The sensors 110 may include any discrete measurement device configured to measure the processing conditions including, but not limited to, temperature sensors, pressure sensors, radiation sensors, chemical sensors, multi-axis accelerometers, multi-axis angular rate sensor, light sensors, barometric pressure sensors, capacitive sensors, time sensors, position sensors, dosage sensors, vibration sensors, or a combination thereof. For example, the sensors 110 may include one or more temperature sensors configured to acquire one or more parameters indicative of temperature. For instance, the one or more temperature sensors may include, but are not limited to, one or more thermocouple (TC) devices (e.g., thermoelectric junction), one or more resistance temperature devices (RTDs) (e.g., thin film RTD), or the like. By way of another example, in the case of pressure measurements, the sensors 110 may include, but are not limited to, a piezoelectric sensor, a capacitive sensor, an optical sensor, a potentiometric sensor or the like. By way of another example, in the case of radiation measurements, the sensors 110 may include, but are not limited to, one or more light detectors (e.g., photovoltaic cell, photoresistor, and the like) or other radiation detectors (e.g., solid state detector). By way of another example, in the case of chemical measurements, the sensors 110 may include, but are not limited to, one or more chemiresistors, gas sensors, pH sensors, or the like. By way of another example, in the case of acceleration measurements, the multi-axis accelerometer may be an acceleration measuring type measuring 3-axis or 6-axis. By way of another example, in the case of rotation rates measurements, the multi-axis angular rate sensor may be a gyroscope. The multi-axis angular rate sensor may measure 3-axis rotation rates. By way of another example, in the case of light measurements, the light sensor may be a light measuring type with an excitation source. By way of another example, in the case of pressure measurements, the barometric pressure sensor may sense local barometric pressure of the process condition measurement device 100. By way of another example, in the case of capacitive measurements, the capacitive sensor may directly gauge a proximity of the process condition measurement device 100 relative to another component. By way of another example, in the case of time measurements, the time sensor may generate one or more time delay parameters. By way of another example, in the case of position measurements, the position sensors may be line sensors or the like. By way of another example, in the case of dosage measurements, the dosage sensors may be in-band dosage sensors, out-of-band dosage sensors, in-band scattered dosage sensors, or the like.

The sensors 110 may be configured to measure the processing conditions across the substrate 102. The sensors 110 may detect gradients in the processing conditions across the substrate 102. By measuring in different areas of the substrate 102, the gradient across the substrate 102 can be calculated, and additionally, the condition at a particular location on the substrate 102 can be determined. The number of the sensors 110 in or on the substrate 102 may vary depending upon the processing condition being measured and the size of the substrate 102.

The process condition measurement device 100 may include the communication interface 112. The communication interface 112 may include any suitable communication interface. For example, the communication interface 112 may include a radio frequency (RF) inductive coil, a light emitting diode (LED) interface, a wireline interface, or the like. The communication interface 112 may be configured to transmit data and/or power. For example, the RF inductive coil may receive data and inductively charge the process condition measurement device 100. The LED interface may also transmit data.

The process condition measurement device 100 may include the interconnects 114. The interconnects 114 may also be referred to as conductive traces or the like. The interconnects 114 may be flex circuits disposed on or embedded in the substrate 102 or fabricated discretely and embedded into the substrate 102. The interconnects 114 may electrically connect one or more components of the process condition measurement device 100. For example, the interconnects 114 may electrically connect the component packages 108, the sensors 110, and/or the communication interface 112.

The process condition measurement device 100 may include the electrical contacts 116. For example, the substrate 102 and/or the cover 104 may include the electrical contacts 116. The electrical contacts 116 may also be referred to as conductive contacts, metal contacts, ohmic contacts, or the like. The electrical contacts 116 of the substrate 102 may be matched to and coincident with the electrical contacts 116 of the cover 104. The electrical contacts 116 may electrically couple between the substrate 102 and the cover 104. The electrical contacts 116 may allow electrical current to flow between the substrate 102 and the cover 104. The electrical contacts 116 may extend through an oxide layer into contact with a bulk layer of the substrate 102 and/or the cover 104. The substrate 102 and the cover 104 may form a single conductive shield that extends around the various components via the electrical contacts 116.

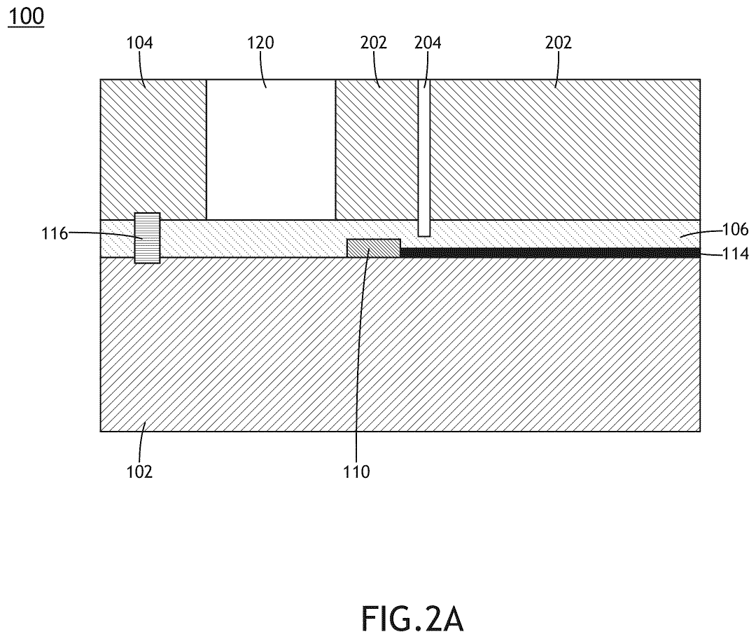

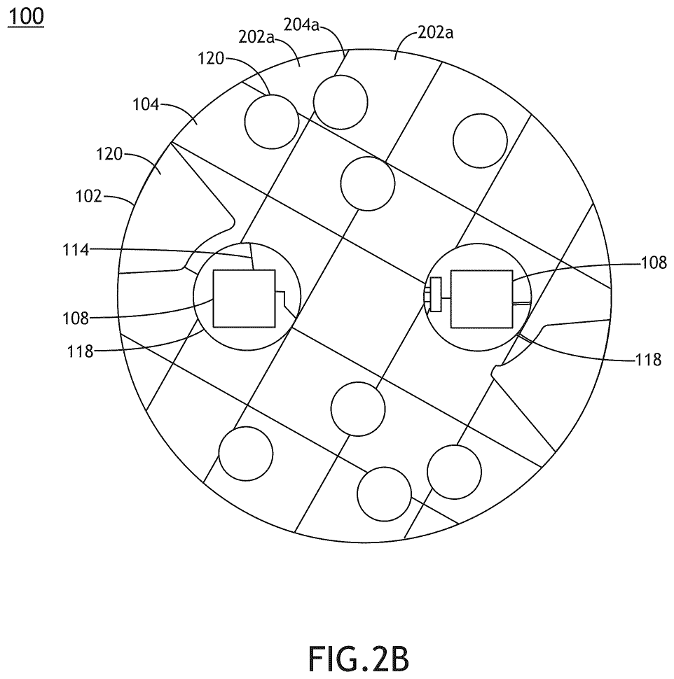

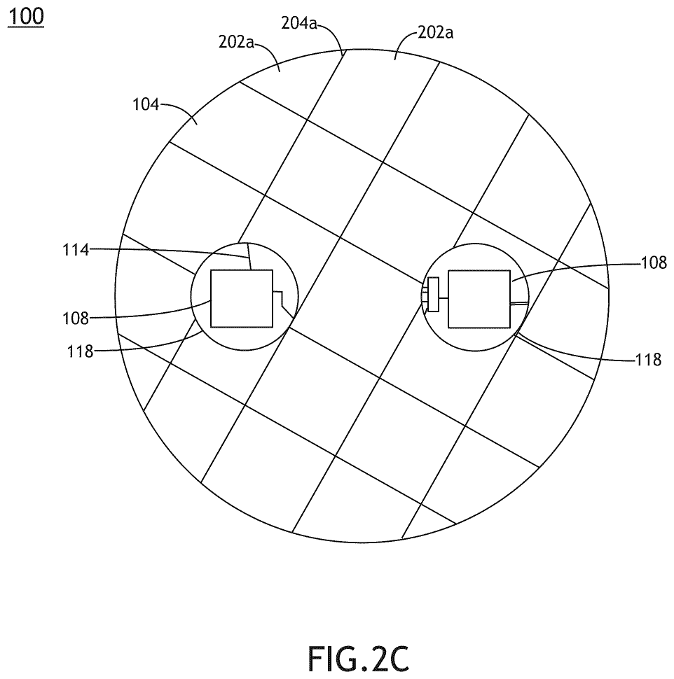

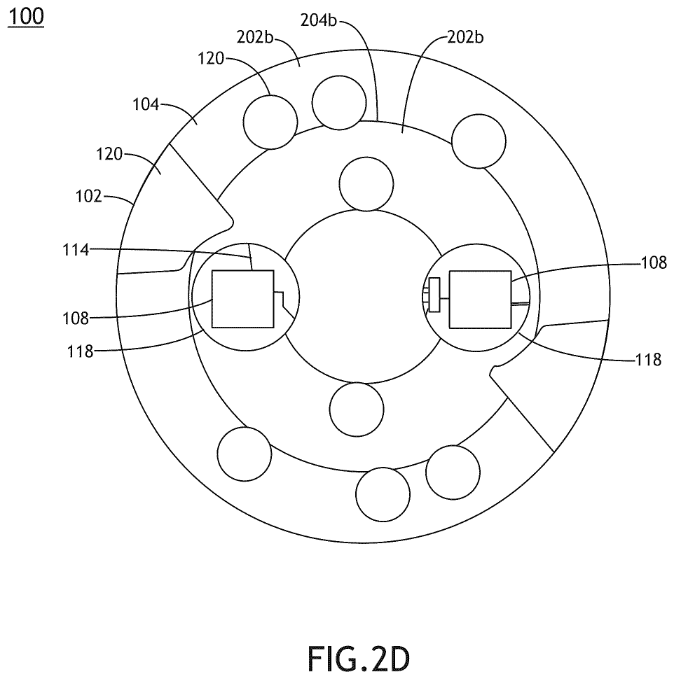

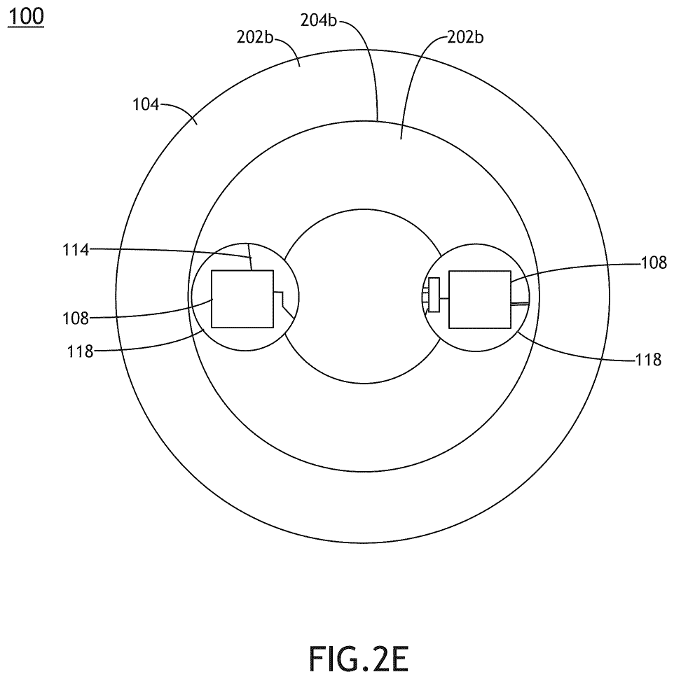

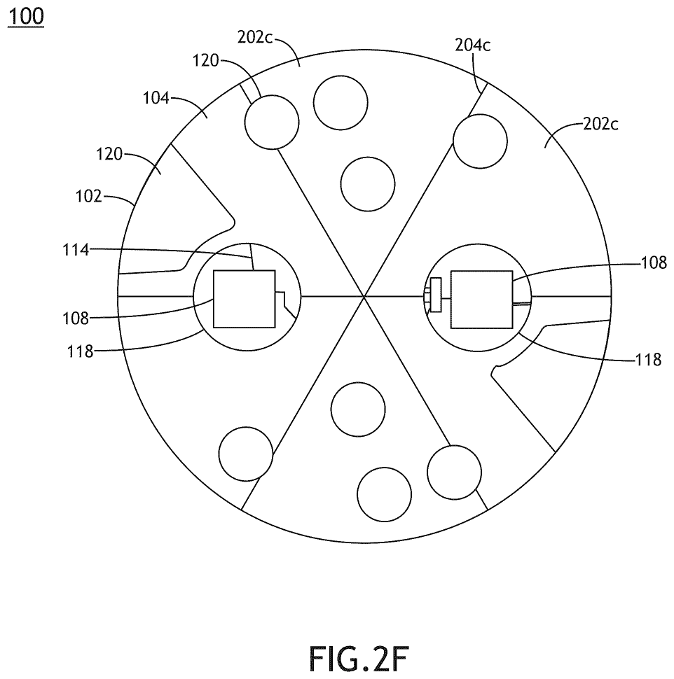

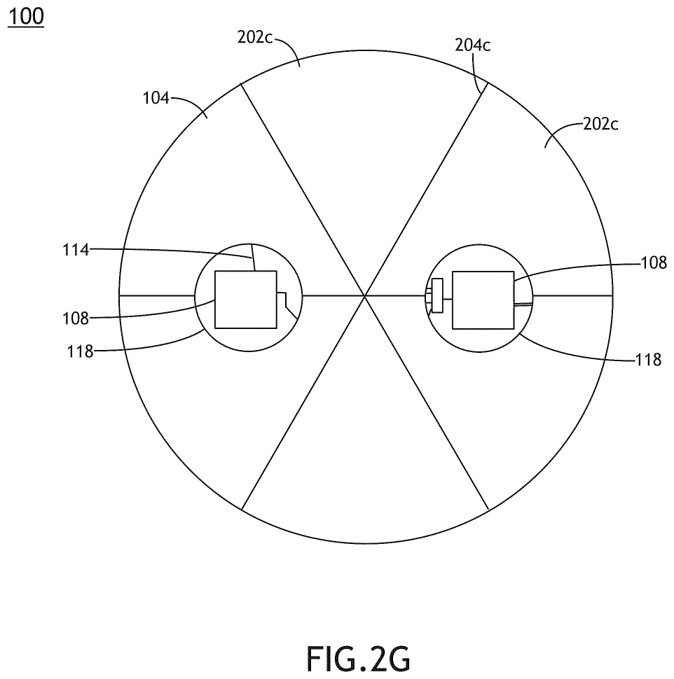

FIGS. 2A-2G illustrate the process condition measurement device 100, in accordance with one or more embodiments of the present disclosure. The discussion of the substrate 102, the cover 104, the adhesive layer 106, the component packages 108, the sensors 110, the communication interface 112, the interconnects 114, the electrical contacts 116, the package-through holes 118, and the blank-through holes 120 of the process condition measurement device 100 is incorporated herein by reference in the entirety. The cover 104 may also include cover sections 202. The cover sections 202 may define grooves 204. The grooves 204 may be defined between the cover sections 202.

The cover sections 202 may be discrete sections of the cover 104. The cover sections 202 may be separated from adjacent of the cover sections 202 by the grooves 204.

The grooves 204 may be defined axially through at least a partial thickness of the cover 104. For example, the grooves 204 may be defined axially through the cover 104. The grooves 204 may be at least as deep as the cover 104. The grooves 204 may or may not be defined into the substrate 102 and/or the adhesive layer 106. For example, the grooves 204 are defined axially through the cover 104 and into the adhesive layer 106 but not into the substrate 102.

The grooves 204 may include a select width. The width of the grooves 204 may also be referred to as a linewidth. The width of the grooves 204 may be based on the thickness of the cover 104. For example, the width of the grooves 204 may be less than the thickness of the cover 104.

The grooves 204 may be disposed over and aligned with one or more of the sensors 110, the communication interface 112, and/or the interconnects 114. The depth of the grooves 204 may be selected such that the grooves 204 are not formed into the sensors 110, the communication interface 112, and/or the interconnects 114. It is noted that aligning the grooves 204 over the sensors 110, the communication interface 112, and/or the interconnects 114 may or may not reduce the shielding of the sensors 110, the communication interface 112, and/or the interconnects 114 provided by the cover 104 which are aligned with the grooves 204.

The cover sections 202 and the grooves 204 may be defined in any suitable shape. For example, the cover sections 202 may be grid-shaped cover sections 202a, sector-shaped cover sections 202b, concentric-shaped cover sections 202c, combinations thereof, or the like. By way of another example, the grooves 204 may be gridded grooves 204a, sectored grooves 204b, concentric grooves 204c, combinations thereof, or the like.

The grid-shaped cover sections 202a may define the gridded grooves 204a. The grid-shaped cover sections 202a and the gridded grooves 204a may be defined in cartesian coordinates. The grid-shaped cover sections 202a may be formed in a grid-shape. The gridded grooves 204a may or may not be defined through a center axis of the cover 104. The gridded grooves 204a may extend laterally and longitudinally through the diameter of the cover 104. The gridded grooves 204a may include lateral grooves and longitudinal grooves, where the lateral grooves may be oriented in parallel to adjacent of the lateral grooves and orthogonal to the longitudinal grooves. The grid-shaped cover sections 202a may include dimensions defined by the gridded grooves 204a and/or the outer diameter of the cover 104. The gridded grooves 204a may include a select spacing between adjacent of the gridded grooves 204a. For example, the spacing between adjacent of the gridded grooves 204a may be at least 50 mm.

The sector-shaped cover sections 202b may define the sectored grooves 204b. The sector-shaped cover sections 202b and the sectored grooves 204b may be defined in polar coordinates. The sector-shaped cover sections 202b may be formed in a sector-shape. The sector-shape may also be referred to as circular sector. The sectored grooves 204b may be defined diametrically through the center axis of the cover 104. The sectored grooves 204b may each extend through the diameter of the cover 104. The sector-shaped cover sections 202b and the sectored grooves 204b may be defined in a polar array with the sectored grooves 204b repeating between adjacent of the sector-shaped cover sections 202b. The sectored grooves 204b may be spaced apart from adjacent of the sectored grooves 204b by a select angle. The number of the sectored grooves 204b, the angle between the sectored grooves 204b, and the diameter of the cover 104 may define the area of the sector-shaped cover sections 202b.

The concentric-shaped cover sections 202c may define the concentric grooves 204c. The concentric-shaped cover sections 202c and the concentric grooves 204c may be defined in polar coordinates. The concentric-shaped cover sections 202c may be formed in concentric-shapes. For example, the innermost of the concentric-shaped cover sections 202c may be a circular shape and the remainder of the concentric-shaped cover sections 202c may be annular shapes which are concentric to the innermost of the concentric-shaped cover sections 202c. The concentric-shaped cover sections 202c and the concentric grooves 204c may be concentric to the center axis of the cover 104. The concentric-shaped cover sections 202c may include a select spacing between adjacent of the concentric-shaped cover sections 202c. For example, the spacing between adjacent of the concentric-shaped cover sections 202c may be at least 50 mm.

The cover 104 may include the package-through holes 118 and/or the blank-through holes 120 in combination with or separately from the cover sections 202 and the grooves 204. For example, the cover 104 may include the package-through holes 118, the cover sections 202, and the grooves 204 and may or may not include the blank-through holes 120. In embodiments, the cover 104 may include the package-through holes 118, the blank-through holes 120, the cover sections 202, and the grooves 204. The package-through holes 118 and/or the blank-through holes 120 may be defined between the cover sections 202. For example, the package-through holes 118 and/or the blank-through holes 120 may be defined between any of the grid-shaped cover sections 202a, the sector-shaped cover sections 202b, and/or the concentric-shaped cover sections 202c.

The grooves 204 may or may not be oriented through the package-through holes 118 and/or the blank-through holes 120. For example, at least some of the grooves 204 may be oriented through the package-through holes 118 and/or the blank-through holes 120. For instance, at least some of the gridded grooves 204a, the sectored grooves 204b, and/or the concentric grooves 204c may be oriented through the package-through holes 118 and/or the blank-through holes 120. The gridded grooves 204a may be oriented laterally and/or longitudinally through the package-through holes 118 and/or the blank-through holes 120. The sectored grooves 204b may be oriented diametrically through the package-through holes 118 and/or the blank-through holes 120. The concentric grooves 204c may be oriented circumferentially through the package-through holes 118 and/or the blank-through holes 120.

The package-through holes 118 and/or the grooves 204 may provide several benefits. The package-through holes 118 and/or the grooves 204 may be beneficial to control a stress in the process condition measurement device 100. For example, the package-through holes 118 and/or the grooves 204 may relieve stress in the substrate 102 caused by adhering the cover 104 to the substrate 102. Relieving the stress may be beneficial to ensure uniformity in the shape of the substrate 102. The package-through holes 118 and/or the grooves 204 may control the stress by increasing the flexibility of the cover 104, allowing the substrate 102 to bend flat the cover 104. For these reasons, it is advantageous to limit the area covered by the cover 104 or relieve the strains caused by excess coverage. The package-through holes 118 and/or the grooves 204 may reduce thermo-mechanical stresses that increase the ability of the process condition measurement device 100 to replicate the thermo-mechanical behavior of a standard wafer. In this regard, the package-through holes 118 and/or the grooves 204 may optimize the cover 104 for superior thermo-mechanical performance. The thermo-mechanical optimization may enable higher precision process condition measurement.

The package-through holes 118, the blank-through holes 120 and/or the grooves 204 may be formed by any suitable process. For example, the package-through holes 118, the blank-through holes 120 and/or the grooves 204 may be formed by dicing, sawing (laser or mechanical), cutting, machining, grinding, etching, or the like, or a combination of processes. In some instances, the dimensions of the grooves 204 may be based on the process used to form the grooves 204. The package-through holes 118, the blank-through holes 120 and/or the grooves 204 may be formed in the cover 104 before and/or after the cover 104 is adhered to the substrate 102.

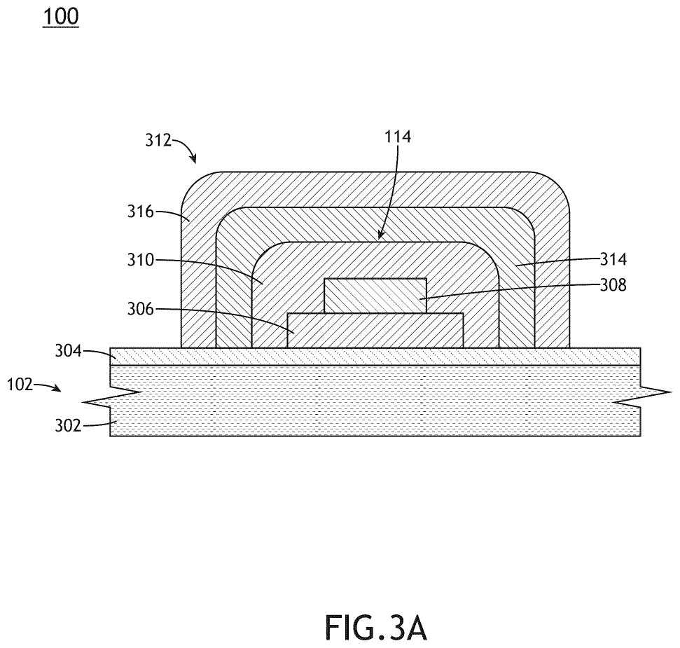

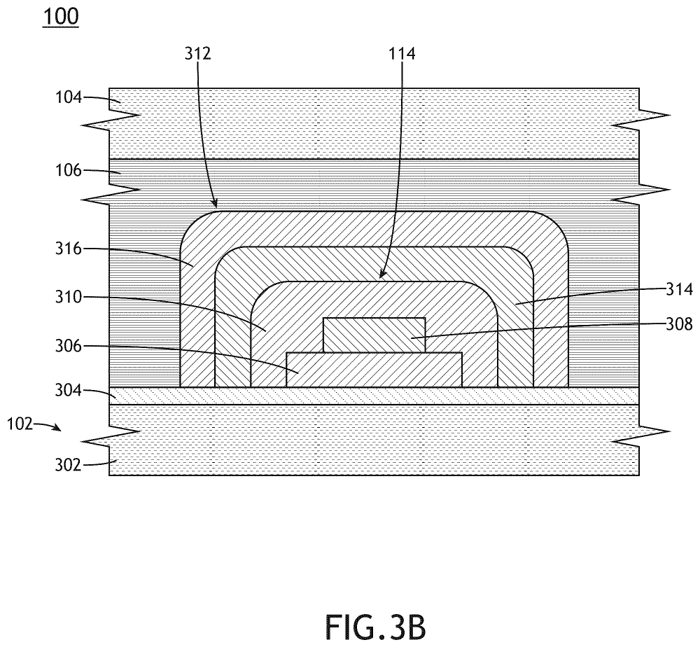

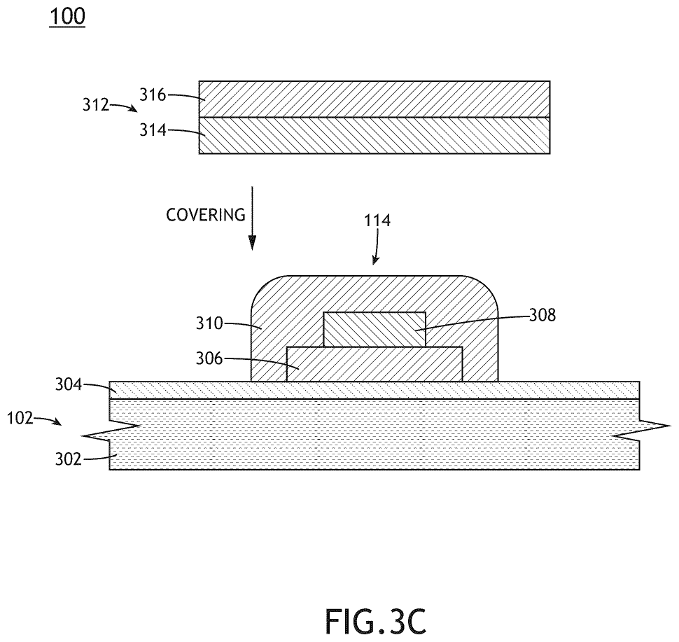

FIGS. 3A-3C illustrate the process condition measurement device 100, in accordance with one or more embodiments of the present disclosure. The discussion of the substrate 102, the cover 104, the adhesive layer 106, the component packages 108, the sensors 110, the communication interface 112, the interconnects 114, the electrical contacts 116, the package-through holes 118, and the blank-through holes 120, the cover sections 202, and the grooves 204 of the process condition measurement device 100 is incorporated herein by reference in the entirety. The process condition measurement device 100 may also include a bulk layer 302, an oxide layer 304, a cap layer 306, an interconnect layer 308, an interconnect-passivation layer 310, a thin-film 312, a conductive shield 314, and/or a thin-film-passivation layer 316. The substrate 102 may include the bulk layer 302 and the oxide layer 304. The interconnects 114 may include the cap layer 306, the interconnect layer 308, and the interconnect-passivation layer 310. The thin-film 312 may include the conductive shield 314 and the thin-film-passivation layer 316.

The bulk layer 302 may be bulk silicon. Various layers may be formed upon the bulk layer 302. The oxide layer 304 may be formed across the bulk layer 302. The oxide layer 304 may be a silicon oxide. For example, the thin-film-passivation layer 316 may be a thermal oxide such as silicon dioxide. For instance, oxide layer 304 may be formed across the bulk layer 302 by thermally oxidizing the bulk layer 302.

The interconnects 114 may be disposed on the substrate 102. For example, the interconnects 114 may be disposed on the oxide layer 304 of the substrate 102. For instance, the cap layer 306 may be disposed on the substrate 102 (e.g., on the oxide layer 304). The cap layer 306 may be disposed between and separate the interconnect layer 308 from the substrate 102. The cap layer 306 may compensate for any defects in the oxide layer 304. The cap layer 306 may include any dielectric material. The interconnect layer 308 may be disposed on the cap layer 306. The width of the cap layer 306 may extend beyond the width of the interconnect layer 308. The interconnect layer 308 may be a conductive layer that may transfers the signals to and from the sensors 110. For example, the interconnect layer 308 may couple between the sensors 110 and the component packages 108. The interconnect layer 308 may be etched to form circuit traces leading to and from the sensors 110, and any bond pads (not depicted) needed for interconnection thereof. The interconnect-passivation layer 310 may be formed over the cap layer 306 and the interconnect layer 308. The interconnect-passivation layer 310 may also be disposed on the substrate 102. For example, the interconnect-passivation layer 310 may be disposed on the oxide layer 304.

The thin-film 312 may be formed over the interconnects 114. For example, the conductive shield 314 may be formed over the interconnects 114. For instance, the conductive shield 314 may be formed over the interconnect-passivation layer 310 of the interconnects 114. The conductive shield 314 may also be disposed on the substrate 102. For example, the conductive shield 314 may be disposed on the oxide layer 304. The interconnect-passivation layer 310 may be disposed between the interconnect layer 308 and the conductive shield 314. The interconnect-passivation layer 310 may also be disposed between the cap layer 306 and the conductive shield 314. The thin-film-passivation layer 316 may be formed over the conductive shield 314. The thin-film-passivation layer 316 may also be disposed on the substrate 102. For example, the thin-film-passivation layer 316 may be disposed on the oxide layer 304. The conductive shield 314 may be disposed between the interconnect-passivation layer 310 and the thin-film-passivation layer 316.

The interconnects 114, the cap layer 306, the interconnect layer 308, the interconnect-passivation layer 310, the thin-film 312, the conductive shield 314, and/or the thin-film-passivation layer 316 may each include selected thicknesses. The thickness of the interconnects 114 may be based on the thicknesses of the cap layer 306, the interconnect layer 308, and/or the interconnect-passivation layer 310. Similarly, the thickness of the thin-film 312 may be based on the thicknesses of the conductive shield 314 and/or the thin-film-passivation layer 316. For example, the thicknesses of the cap layer 306, the interconnect layer 308, the interconnect-passivation layer 310, the conductive shield 314, and/or the thin-film-passivation layer 316 may be on the order of hundreds of nanometers to single digit micrometers.

The width of the thin-film 312 may terminate along the width of the interconnects 114. For example, the width of the thin-film 312 may extend by a few micrometers from the width of the interconnects 114. The thin-film 312 may not cover the entire diameter of the substrate 102 by terminating at the width of the interconnects 114. Eliminating as much coverage of the substrate 102 with the thin-film 312 may be beneficial to reduce stresses which may be imparted on the substrate 102 by the thin-film 312.

The interconnect layer 308 and/or the conductive shield 314 may be formed of any suitable conductive material. For example, the interconnect layer 308 and/or the conductive shield 314 may be a metal (e.g., aluminum) or another suitable conductor.

The interconnect-passivation layer 310 and/or the thin-film-passivation layer 316 may be formed of any suitable passivation material. For example, the interconnect-passivation layer 310 and/or the thin-film-passivation layer 316 may include a nitride layer, an oxide layer, a polyimide passivation layer, or the like.

The thin-film 312 may provide electrical insulation and/or shielding to the interconnects 114 traces and/or protect the interconnects 114 from plasma species. For example, the conductive shield 314 may act as an electrical shield for the interconnect layer 308, preventing the interconnect layer 308 from receiving radio frequency signals. By way of another example, the thin-film-passivation layer 316 may protect the conductive shield 314 and the interconnects 114 from the plasma species.

The thin-film 312 may be formed over the interconnects 114 via any suitable process. For example, the thin-film 312 may be a discrete film before being formed over the interconnects 114, which may be applied by laminating to the interconnects 114 and the substrate 102. By way of another example, the thin-film 312 may be deposited onto the interconnects 114. The thin-film 312 may be deposited onto the interconnects 114 via sputtering, evaporation, or the like. The interconnects 114, the cap layer 306, the interconnect layer 308, the interconnect-passivation layer 310, the thin-film 312, the conductive shield 314, and/or the thin-film-passivation layer 316 may be made with thick metal, polymer, and insulative films as well as discrete films such as polymers and metal foils, and flex and non-flexible PCBs. In this regard, the specifics of how the interconnects 114 and/or the thin-film 312 are formed is not intended to be limiting.

The process condition measurement device 100 may include the interconnects 114 and the thin-film 312 in combination with or separately from the cover 104 and the adhesive layer 106. For example, the process condition measurement device 100 may include the interconnects 114 and the thin-film 312 and may or may not include the cover 104 which may or may not include the package-through holes 118, the blank-through holes 120, the cover sections 202, and/or the grooves 204. In embodiments, the process condition measurement device 100 may include the interconnects 114, the thin-film 312, the cover 104, and the adhesive layer 106, with the cover 104 including the package-through holes 118, the blank-through holes 120, the cover sections 202, and/or the grooves 204. The adhesive layer 106 may be formed over the thin-film 312. The package-through holes 118, the blank-through holes 120, and/or the grooves 204 may not be defined into the thin-film 312. It is contemplated that the thin-film 312 may be beneficial to protect the portions of the interconnects 114 which are uncovered by the grooves 204. The process condition measurement device 100 may include any suitable permutation of the cover 104, the adhesive layer 106, the interconnects 114, the package-through holes 118, the blank-through holes 120, the cover sections 202, the grooves 204, the thin-film 312, and the like.

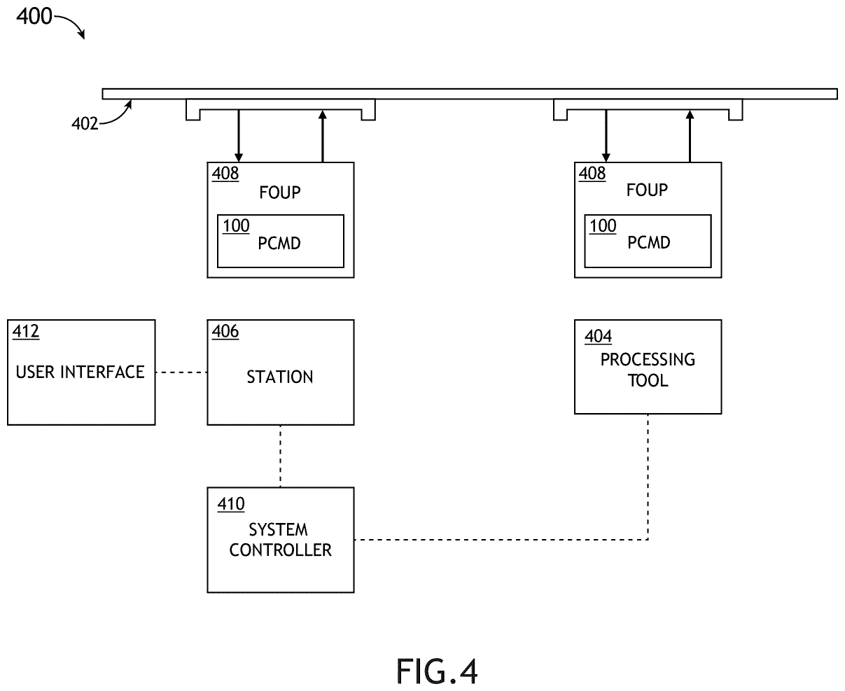

FIG. 4 depicts a simplified block diagram of a system 400, in accordance with one or more embodiments of the present disclosure. The system 400 may be a substrate processing system. The system 400 may include the process condition measurement device 100, an automatic material handling system 402 (AMHS), a processing tool 404, a station 406, front opening unified pods 408 (FOUP), a system controller 410, and/or a user interface 412.

The front opening unified pods 408 may be automation ready FOUPs that can communicate to a device manufacturer's fab automation system. The front opening unified pods 408 may include one or more of the process condition measurement devices 100. The front opening unified pods 408 may be configured to receive and secure the process condition measurement devices 100. The process condition measurement device 100 may be housed within the front opening unified pods 408. The front opening unified pods 408 may include a substrate carrier which may be integrated with the system 400. The front opening unified pods 408 may provide an environment for storing and transporting the process condition measurement device 100.

The front opening unified pods 408 may be configured to provide power to the component packages 108. For example, the front opening unified pods 408 may recharge the component packages 108.

The front opening unified pods 408 may be configured to exchange data with the communication interface 112. For example, the front opening unified pods 408 may be configured to receive the sensor measurements from the communication interface 112. The component packages 108 of the process condition measurement device 100 may be communicatively coupled to the front opening unified pods 408 by wireless communication. For instance, the front opening unified pods 408 may include communication circuitry (not depicted). The communication circuitry may include, but is not limited to, one or more communication antennas (e.g., communication coil). The communication circuitry may be configured to establish a communication link between the component packages 108 and the front opening unified pods 408. The front opening unified pods 408 may include a FOUP interface (not depicted). The FOUP interface may be the interface by which the front opening unified pods 408 may be configured to receive recipes, mission start command, relays back mission data, and the like.

The automatic material handling system 402 may position the front opening unified pods 408 in three-dimensions. The automatic material handling system 402 may include an Overhead track (OHT) system. The space occupied by the automatic material handling system 402 may be above the normal floor working level. The automatic material handling system 402 may pick the front opening unified pods 408 from the station 406 and transport the front opening unified pods 408 to the processing tool 404. Similarly, the automatic material handling system 402 may pick the front opening unified pods 408 from the processing tool 404 and transport the front opening unified pods 408 to the station 406.

The station 406 may be an automation station. The station 406 may be an Automated material handling system (AMHS) compatible station. The station 406 may host the front opening unified pods 408. The station 406 may be configured to receive the front opening unified pods 408. The station 406 may communicate with the front opening unified pods 408. The station 406 may also recharge the front opening unified pods 408. The station 406 may communicate with the system controller 410. The station 406 may also be configured to communicate with the factory automation system.

The processing tool 404 may be configured to receive the process condition measurement device 100. The automatic material handling system 402 may also be configured to remove the process condition measurement device 100 from the front opening unified pods 408 and place the process condition measurement device 100 within a pathway of the illumination.

The process condition measurement device 100 may include a thickness which is sufficiently small to meet a specification of a processing chamber (e.g., epitaxy chamber, plasma etch chamber) of the processing tool 404. For example, the process condition measurement device 100 may include a maximum thickness of 50 mm or less to fit into various process chambers. For instance, the maximum thickness may be 50 mm or less, 10 mm or less, 6 mm or less, 5 mm or less, 2 mm or less, or smaller.

The processing tool 404 may be configured to generate illumination. The processing tool 404 may be configured to generate the illumination using a plasma or the like. For example, the processing tool 404 may include an EUV lithography tool or the like. The processing tool 404 may generate the illumination in an image plane on the process condition measurement device 100.

The process condition measurement device 100 may be configured to monitor process conditions within a process chamber of the processing tool 404. The process condition measurement device 100 may provide a metrology platform for calibrating and monitoring the illumination in the processing tool 404. The processing tool 404 may use the sensor measurements for optimal semiconductor process performance.

The process condition measurement device 100 may be subject to extreme conditions within the processing tool 404. The extreme conditions may include including aggressive chemistry, high and low temperature extremes. The extreme conditions may be found in etch environments or other wafer processing environments. The material of the substrate 102, the cover 104, and/or the thin-film 312 may cause negligible contamination in the processing tool 404. The substrate 102, the cover 104, and/or the thin-film 312 may shield the sensors 110, the communication interface 112, the interconnects 114, and/or the electrical contacts 116 from extreme conditions (e.g., high RF, high heat flux, high electromagnetic radiation) within process chambers of the processing tool 404. Thus, the process condition measurement device 100 may include the sensors 110, the communication interface 112, the interconnects 114, and/or the electrical contacts 116 which may survive the extreme environments.

The process condition measurement device 100 may be configured to autonomously perform a measurement of the illumination in response to a factory automation request.

The system controller 410 and the process condition measurement device 100 may include an interface through the front opening unified pods 408 and the station 406 and/or an interface through the processing tool 404. The system controller 410 may process data from the process condition measurement device 100 for statistical processing control (SPC). The system 400 may have the ability to automatically add data collected from the process condition measurement device 100 to a database within the system controller 410.

A mission may be a data collection session of the process condition measurement device 100 and the following download of data from the process condition measurement device 100. The mission may be initiated by the system controller 410 for the purpose to ascertain the health of the processing tool 404. The mission may be communicated to the station 406 that hosts the front opening unified pods 408. The station 406 may communicate the mission to the front opening unified pods 408. The front opening unified pods 408 may then communicate the mission to the process condition measurement device 100. The process condition measurement device 100 may then execute the mission for determining the health of the processing tool 404.

The user interface 412 may be communicatively coupled to the station 406. The user interface 412 may include, but is not limited to, one or more desktops, laptops, tablets, and the like. The user interface 412 may include a display used to display data of the system to a user. The display of the user interface 412 may include any display known in the art. For example, the display may include, but is not limited to, a liquid crystal display (LCD), an organic light-emitting diode (OLED) based display, or a CRT display. Those skilled in the art should recognize that any display device capable of integration with a user interface is suitable for implementation in the present disclosure. A user may input selections and/or instructions responsive to data displayed to the user via a user input device of the user interface 412.

Any of the various components of the system 400 may be configured to communicate using a selected communications protocol. For example, the selected communications protocol may include an industry standard communications protocol consistent with standards defined by the Semiconductor Equipment and Materials Institute (SEMI). These standards are referred to as SEMI Equipment Communications Standards (SECS) and Generic Equipment Model (GEM).

Referring generally again to the figures. Processing conditions may refer to various processing parameters used in manufacturing an integrated circuit. Processing conditions may include any parameter used to control semiconductor manufacture or any condition a manufacturer would desire to monitor such as, but not limited to, temperature, processing chamber pressure, gas flow rate within the chamber, gaseous chemical composition within the chamber, position within a chamber, ion current density, ion current energy, light energy density, and vibration and acceleration of a wafer or other substrate within a chamber or during movement to or from a chamber. Different processes will inevitably be developed over the years, and the processing conditions will, therefore, vary over time. Therefore, whatever the conditions may be, it is foreseen that the embodiments described will be able to measure such conditions.

Although the cover 104 is described as cover wafer which includes the wafer material, this is not intended to be limiting. It is further contemplated that the cover 104 may be a discrete-film cover. The discrete-film cover may include, but is not limited to, a polyimide, a metal-coated polyimide, an insulation-coated metal foil, a Kapton™ film, or the like. It is noted that the discrete-film cover may include any of the various features of the cover 104, such as defining any of the package-through holes 118, the blank-through holes 120, the cover sections 202, and/or the grooves 204. The discrete-film cover may be applied to the substrate 102. The discrete-film cover may also be used in combination with the thin-film 312 over the interconnects 114.

The sensors 110 may be discrete sensors. The thin-film-passivation layer 316, the conductive shield 314, and/or the interconnect-passivation layer 310 may be etched through to connect the sensors 110 to the interconnect layer 308. The sensors 110 may also avoid coupling to the conductive shield 314 when coupling to the interconnect layer 308.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive, and the like. The memory medium may include flash memory cells, or other type memory, discrete EPROM or EEPROM, or the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet, and the like).

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask, and reticle should be interpreted as interchangeable.

A communication interface may communicate using any suitable protocol, such as, but not limited to, a wireline communication protocol or wireless communication protocol. For example, the wireline communication protocol may include DSL-based interconnection, cable-based interconnection, T9-based interconnection, USB, and the like. By way of another example, the wireless communication protocol may include GSM, GPRS, CDMA, EV-DO, EDGE, WiMAX, 3G, 4G, 4G LTE, 5G, Wi-Fi protocols, RF, Bluetooth, Intermediate System to Intermediate System (IS-IS), radio frequency identification (RFID) protocols, open-sourced radio frequencies, and the like. The communication interface may use On-Off keying and backscatter modulation for bidirectional data transfer together with inductive power transfer for battery charging. Accordingly, an interaction between the various devices may be determined based on one or more characteristics including, but not limited to, cellular signatures, IP addresses, MAC addresses, Bluetooth signatures, radio frequency identification (RFID) tags, and the like. The wireless communication may include wireless nearfield communication.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all its material advantages. The form described is merely explanatory, and it is the intention of the following claims to encompass and include such changes. Furthermore, it is to be understood that the invention is defined by the appended claims.

What is claimed:

1. A process condition measurement device comprising:
a substrate;
a cover disposed above and covering the substrate, wherein the cover extends across the substrate, wherein the cover defines a plurality of blank-through holes, wherein the plurality of blank-through holes is defined axially through the cover;
a plurality of sensors configured to measure processing conditions across the substrate; and
a plurality of interconnects electrically connecting the plurality of sensors, wherein the plurality of sensors and the plurality of interconnects are disposed on or embedded within the substrate, wherein the plurality of blank-through holes is offset from the plurality of sensors and the plurality of interconnects.

2. The process condition measurement device of claim 1, wherein at least one of the substrate or the cover comprises at least one of silicon, glass, aluminum oxide, silicon carbide, or quartz.

3. The process condition measurement device of claim 2, wherein the cover comprises at least one of silicon, glass, aluminum oxide, silicon carbide, quartz, polyimide, or metal coated polyimide.

4. The process condition measurement device of claim 2, wherein the substrate comprises at least one of silicon, glass, aluminum oxide, silicon carbide, or quartz; wherein the cover comprises a metal-coated polyimide.

5. The process condition measurement device of claim 1, wherein the process condition measurement device comprises a thickness of 50 mm or less.

6. The process condition measurement device of claim 5, wherein the process condition measurement device comprises a thickness of 10 mm or less.

7. The process condition measurement device of claim 1, comprising an adhesive layer, wherein the adhesive layer is disposed between and adheres together the substrate and the cover.

8. The process condition measurement device of claim 1, wherein the plurality of blank-through holes is at least one of radially or circumferentially offset from the plurality of sensors and the plurality of interconnects.

9. The process condition measurement device of claim 1, comprising a plurality of electrical contacts, wherein the plurality of electrical contacts electrically couple between the substrate and the cover, wherein the cover is disposed over and covers the plurality of electrical contacts, wherein the plurality of blank-through holes is offset from the plurality of electrical contacts.

10. The process condition measurement device of claim 1, comprising a plurality of component packages, wherein the plurality of component packages is disposed on or embedded within the substrate, wherein the cover defines a plurality of package-through holes, wherein the plurality of component packages is aligned with and extend axially through the plurality of package-through holes, wherein the plurality of blank-through holes is offset from the plurality of component packages and the plurality of package-through holes.

11. The process condition measurement device of claim 1, wherein the cover comprises a plurality of cover sections, wherein the plurality of cover sections define the plurality of blank-through holes and a plurality of grooves, wherein the plurality of grooves is defined axially through at least a partial thickness of the cover.

12. The process condition measurement device of claim 11, wherein at least one of the plurality of grooves is disposed over at least one of the plurality of interconnects.

13. The process condition measurement device of claim 12, wherein the plurality of grooves is defined axially through the cover.

14. The process condition measurement device of claim 13, wherein the plurality of grooves do not extend into the substrate and the plurality of interconnects.

15. The process condition measurement device of claim 11, wherein the plurality of cover sections comprise a plurality of grid-shaped cover sections, wherein the plurality of grooves comprise a plurality of gridded grooves.

16. The process condition measurement device of claim 11, wherein the plurality of cover sections comprise a plurality of sector-shaped cover sections, wherein the plurality of grooves comprise a plurality of sectored grooves.

17. The process condition measurement device of claim 11, wherein the plurality of cover sections comprise a plurality of concentric-shaped cover sections, wherein the plurality of grooves comprise a plurality of concentric grooves.

18. The process condition measurement device of claim 11, wherein at least one of the plurality of grooves is oriented through at least one of the plurality of blank-through holes.

19. The process condition measurement device of claim 1, wherein the plurality of interconnects comprise:
a cap layer, wherein the cap layer is disposed on the substrate;
an interconnect layer, wherein the interconnect layer is disposed on the cap layer, wherein a width of the cap layer extends beyond a width of the interconnect layer; and
an interconnect-passivation layer, wherein the interconnect-passivation layer is formed over the cap layer and the interconnect layer, wherein the interconnect-passivation layer is disposed on the substrate.

20. The process condition measurement device of claim 19, comprising a thin-film, wherein the thin-film is formed over the plurality of interconnects, wherein the thin-film comprises:
a conductive shield, wherein the conductive shield is formed over the interconnect-passivation layer and disposed on the substrate; and
a thin-film-passivation layer, wherein the thin-film-passivation layer is formed over the conductive shield and disposed on the substrate.

21. The process condition measurement device of claim 20, wherein a width of the thin-film terminates along a width of the plurality of interconnects.

22. The process condition measurement device of claim 20, wherein at least one of the interconnect-passivation layer or the thin-film-passivation layer comprises at least one of a nitride layer, an oxide layer, or a polyimide passivation layer.

23. A system comprising:
a process condition measurement device comprising:
a substrate;
a cover disposed above and covering the substrate, wherein the cover extends across the substrate, wherein the cover defines a plurality of blank-through holes, wherein the plurality of blank-through holes is defined axially through the cover;
a plurality of sensors configured to measure processing conditions across the substrate; and
a plurality of interconnects electrically connecting the plurality of sensors, wherein the plurality of sensors and the plurality of interconnects are disposed on or embedded within the substrate, wherein the plurality of blank-through holes is offset from the plurality of sensors and the plurality of interconnects; and
a front opening unified pod configured to receive the process condition measurement device.

24. A process condition measurement device comprising:
a substrate;
a cover disposed above and covering the substrate, wherein the cover extends across the substrate, wherein the cover comprises a plurality of cover sections, wherein the plurality of cover sections define a plurality of grooves, wherein the plurality of grooves is defined axially through at least a partial thickness of the cover;
a plurality of sensors configured to measure processing conditions across the substrate; and
a plurality of interconnects electrically connecting the plurality of sensors, wherein the plurality of sensors and the plurality of interconnects are disposed on or embedded within the substrate.

25. A process condition measurement device comprising:
a substrate;
a plurality of sensors configured to measure processing conditions across the substrate;
a plurality of interconnects electrically connecting the plurality of sensors, wherein the plurality of sensors and the plurality of interconnects are disposed on or embedded within the substrate, wherein the plurality of interconnects comprise:
a cap layer disposed on the substrate;
an interconnect layer disposed on the cap layer, wherein a width of the cap layer extends beyond a width of the interconnect layer; and
an interconnect-passivation layer formed over the cap layer and the interconnect layer, wherein the interconnect-passivation layer is disposed on the substrate; and
a thin-film formed over the plurality of interconnects, wherein the thin-film comprises:
a conductive shield formed over the interconnect-passivation layer and disposed on the substrate; and
a thin-film-passivation layer formed over the conductive shield and disposed on the substrate.
